(19) United States
(12) Patent Application Publication
(10) Pub. No.: US 2017/0104037 A1
(43) Pub. Date: Apr. 13, 2017

(54) ORGANIC LIGHT EMITTING DIODE DISPLAY

(71) Applicant: Samsung Display Co., Ltd., Yongin-si (KR)

(72) Inventor: Dong Gyu KIM, Yongin-si (KR)

(21) Appl. No.: 15/131,380

(22) Filed: Apr. 18, 2016

(30) Foreign Application Priority Data
Oct. 12, 2015 (KR) 10-2015-0142225

(51) Int. Cl. H01L 27/32; H01L 51/52; H01L 51/56; H01L 51/50

(52) U.S. Cl. CPC H01L 27/3213; H01L 27/322; H01L 51/504; H01L 51/5088; H01L 51/5056; H01L 51/5072; H01L 51/5206; H01L 51/5234; H01L 51/56

(57) ABSTRACT

An organic light emitting diode (OLED) display includes a substrate, a first electrode disposed on the substrate, first organic emission layers disposed on the first electrode, second organic emission layers disposed on the first organic emission layers, a second electrode disposed on the second organic emission layer, and a color filter layer disposed on the second electrode. The first electrode includes a first sub-electrode, a second sub-electrode, a third sub-electrode, and a fourth sub-electrode spaced apart from each other. The first organic emission layers overlap the first, second, third, and fourth sub-electrodes, the second organic emission layers overlap the first, second, and third sub-electrodes, and the second electrode overlaps the first, second, third, and fourth sub-electrodes. The color filter layer includes sub-color filters.

### CROSS-REFERENCE TO RELATED APPLICATION

This application claims priority from and the benefit of Korean Patent Application No. 10-2015-0142225, filed on Oct. 12, 2015, which is hereby incorporated by reference for all purposes as if fully set forth herein.

### BACKGROUND

Field

Exemplary embodiments relate to an organic light emitting diode device, and, more particularly, to an organic light emitting diode device with reduced power consumption.

Discussion of the Background

Display devices may include a liquid crystal display (LCD), a plasma display panel (PDP), an organic light emitting diode (OLED) device, a field effect display (FED), an electrophoretic display device, and the like.

An OLED display may include two electrodes and an organic emission layer disposed between the two electrodes, which may emit light when an electron injected from one electrode and a hole injected from the other electrode recombine with each other in the organic emission layer, to form an exciton and the exciton discharges energy.

Since an OLED device has a self-luminance characteristic and does not require a separate light source, unlike an LCD, the thickness and weight thereof may be reduced. Further, since OLED devices have high-grade characteristics, such as low power consumption, high luminance, and a high response speed, OLED devices have received attention as a next-generation display device.

In an OLED display, a blue organic emission layer may be deposited on each sub-pixel therein, and then red and green organic emission layers may be deposited on the corresponding sub-pixels. However, for the separate deposition of the red organic emission layer and the green organic emission layer on each sub-pixel, an additional mask may be utilized, which may increase deposition process time and manufacturing costs thereof.

The above information disclosed in this Background section is only to enhancement of understanding of the background of the inventive concept, and, therefore, it may contain information that does not form the prior art that is already known in this country to a person of ordinary skill in the art.

### SUMMARY

Exemplary embodiments of the present invention provide an organic light emitting diode (OLED) display having reduced time and cost for forming an organic emission layer on sub-pixels of each pixel.

Additional aspects will be set forth in the detailed description which follows, and, in part, will be apparent from the disclosure, or may be learned by practice of the inventive concept.

According to an exemplary embodiment of the present invention, an organic light emitting diode (OLED) display includes a substrate, a first electrode disposed on the substrate, first organic emission layers disposed on the first electrode, second organic emission layers disposed on the first organic emission layers, a second electrode disposed on the second organic emission layer, and a color filter layer disposed on the second electrode. The first electrode includes a first sub-electrode, a second sub-electrode, a third sub-electrode, and a fourth sub-electrode spaced apart from each other. The first organic emission layers overlap the first, second, third, and fourth sub-electrodes, the second organic emission layers overlap the first, second, and third sub-electrodes, and the second electrode overlaps the first, second, third, and fourth sub-electrodes. The color filter layer includes sub-color filters.

According to an exemplary embodiment of the present invention, a method of forming an organic light emitting diode (OLED) display includes forming a first electrode on a substrate, the substrate including a first area including a first sub-electrode, a second sub-electrode, a third sub-electrode of the first electrode, and a second area including a fourth sub-electrode of the first electrode, forming a first organic emission layer in the first and second areas, forming a second organic emission layer in the first area, forming a second electrode in the first and second areas, and forming a color filter layer on the second electrode, in which the first and second organic emission layers are respectively configured to emit blue and yellow light.

According to exemplary embodiments of the present invention, costs and processing time associated with forming an organic emission layer on sub-pixels of a pixel of an OLED device may be reduced. Further, power consumption of the OLED display may be reduced by reducing the current used in each sub-pixel.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is an equivalent circuit diagram of a sub-pixel in an organic light emitting diode (OLED) display according to an exemplary embodiment of the present invention.

FIG. 2 is a schematic layout view of an OLED display according to an exemplary embodiment of the present invention.

FIG. 3 is a schematic cross-sectional view of an OLED display according to an exemplary embodiment of the present invention.

FIG. 4 is a schematic cross-sectional view of an OLED display according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

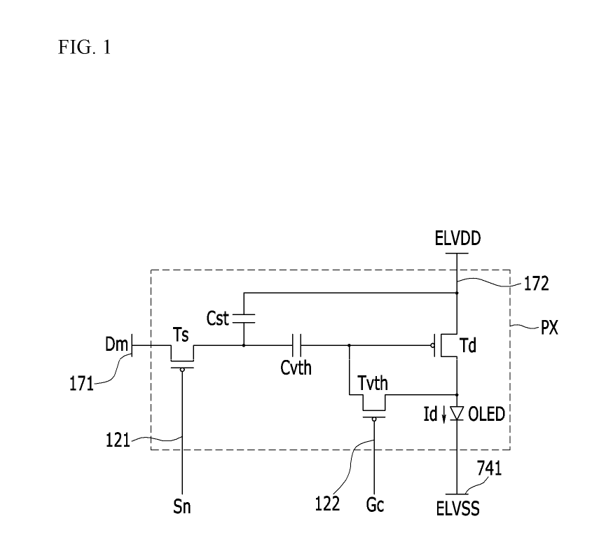

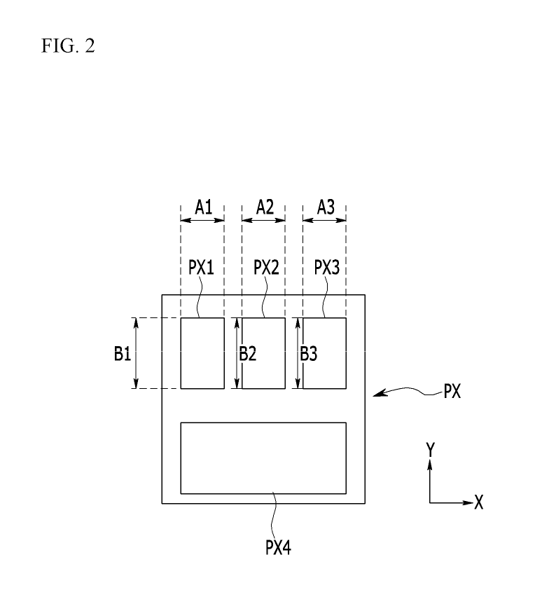

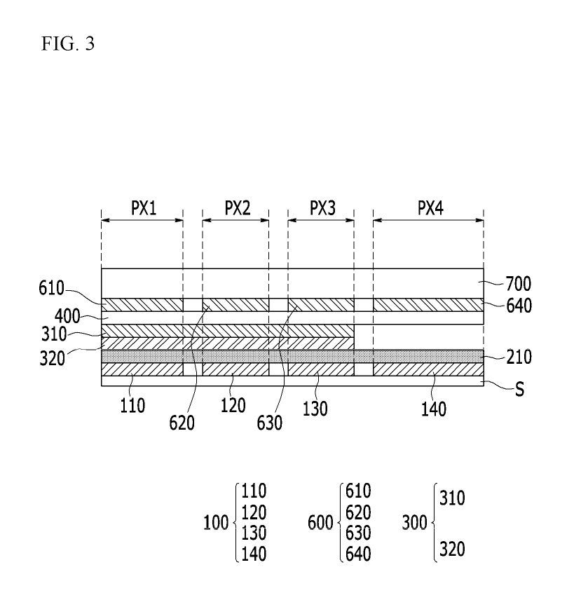

Hereinafter, an organic light emitting diode (OLED) display according to an exemplary embodiment will be described with reference to FIG. 1, FIG. 2, and FIG. 3.

The OLED display according to the present exemplary embodiment may include pixels. Each pixels may include sub-pixels. As used herein, a sub-pixel may be a minimum unit that may represent a primary color, such as red, green, yellow, or blue, and each pixel may display a specific color through a combination of sub-pixels displaying their respective colors.

Referring to FIG. 2, each pixel PX of the OLED display may include a first sub-pixel PX1, a second sub-pixel PX2, a third sub-pixel PX3, and a fourth sub-pixel PX4. The first sub-pixel PX1, the second sub-pixel PX2, the third sub-pixel PX3, and the fourth sub-pixel PX4 are disposed to be spaced apart from each other. The first sub-pixel PX1 emits red light and the second sub-pixel PX2 emits green light. The third sub-pixel PX3 emits yellow light, and the fourth sub-pixel PX4 emits blue light.

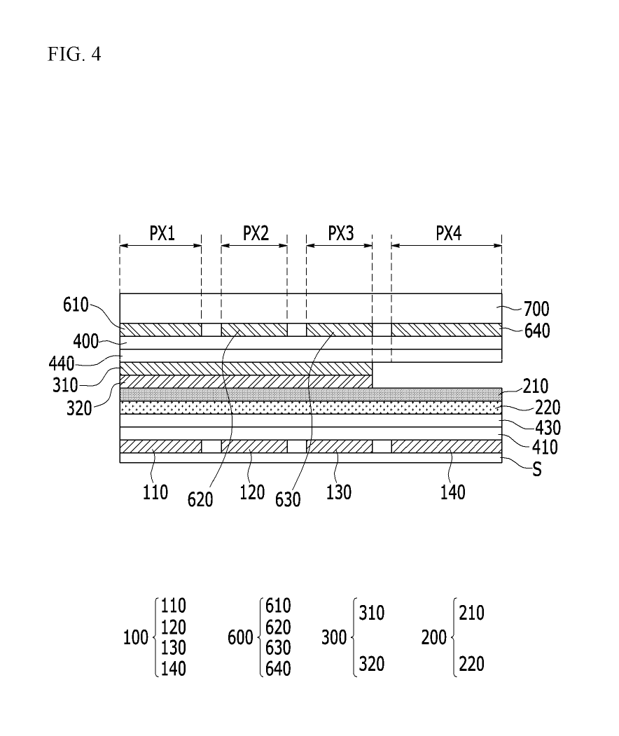

Referring to FIG. 2 and FIG. 3, the first sub-pixel PX1, the second sub-pixel PX2, and the third sub-pixel PX3 may realize respective colors of red, green, and yellow, by transmitting white light, which is a combination of blue light emitted from a first organic emission layer 210 and yellow light emitted from a second organic emission layer 300, through respective color filter layer 600. This will be described in detail later with reference to FIGS. 3 and 4.

Hereinafter, a detailed structure of a pixel of the OLED display and the operation mechanism of a sub-pixel of the OLED display will be described with reference to FIG. 1.

FIG. 1 is an equivalent circuit diagram of a sub-pixel of the OLED display according to an exemplary embodiment of the present invention.

As shown in FIG. 1, a sub-pixel PX of the OLED display according to the present exemplary embodiment includes signal lines 121, 122, 171, and 172, transistors Td, Ts, and Tvth connected to the signal lines, capacitors Cst and Cvth, and an organic light emitting diode OLED. The sub-pixel PX of FIG. 1 corresponds to sub-pixels PX1, PX2, PX3, and PX4 of FIG. 2 to FIG. 4.

The transistors Td, Ts, and Tvth include a driving transistor Td, a switching transistor Ts, and a compensation transistor Tvth. The capacitors Cst and Cvth include a storage capacitor Cst and a compensation capacitor Cvth.

The signal lines 121, 122, 171, and 172 include a gate line 121 transmitting a scan signal Sn, a compensation control line 122 transmitting a compensation control signal Gc, a data line 171 transmitting a data voltage Dm, and a driving voltage line 172 transmitting a driving voltage ELVDD to the driving transistor Td.

A gate electrode of the driving transistor Td is connected with one end of the compensation capacitor Cvth, a source electrode of the driving transistor Td, and a drain electrode of the driving transistor Td is electrically connected with an anode of the organic light emitting diode OLED.

A gate electrode of the compensation transistor Tvth is connected with a compensation control line 122, a source electrode of the compensation transistor Tvth is connected with the drain electrode of the driving transistor Td and the anode of the organic light emitting diode OLED, and a drain electrode of the compensation transistor Tvth is connected with one end of the compensation capacitor Cvth and the gate electrode of the driving transistor Td.

The compensation transistor Tvth is turned on according to a compensation control signal Gc received through the compensation control line 122. The compensation transistor Tvth diode-connects the driving transistor Td by connecting the gate electrode and the drain electrode of the driving transistor Td. While the driving transistor Td is being diode-connected, a voltage corresponding to a threshold voltage of the driving transistor Td is applied to the compensation capacitor Cvth.

A gate electrode of the switching transistor Ts is connected with the gate line 121, a source electrode of the switching transistor Ts is connected with the data line 171, a drain electrode of the switching transistor Ts is connected with the other end of the storage capacitor Cst and the other end of the compensation capacitor Cvth. The switching transistor Ts is turned on according to a scan signal Sn transmitted through the gate line 121.

One end of the storage capacitor Cst is connected with the driving voltage line 172, and a gate-source voltage of the driving transistor Td is determined according to a voltage applied to the compensation capacitor Cvth and the storage capacitor Cst. A cathode of the organic light emitting diode OLED is connected with a common voltage line 741 that transmits the common voltage ELVSS. The organic light emitting diode OLED emits light by a driving current Id transmitted through the driving transistor Td from the driving voltage line 172, and the driving current Id flows to the common voltage line 741. It is noted that, however, the structure and configuration of a sub-pixel, such as the number of transistors and capacitors therein, may be varied.

Hereinafter, a detailed structure of an OLED display according to an exemplary embodiment of the present invention will be described with reference to FIG. 3.

FIG. 3 is a schematic cross-sectional view of an OLED display according to an exemplary embodiment of the present invention.

Referring to FIG. 3, a substrate S may be an insulating substrate made of glass, quartz, ceramic, or plastic. The substrate S may be flexible.

A first electrode 100, which may be a pixel electrode, is disposed on the substrate S. According to the present exemplary embodiment, the first electrode 100 includes a first sub-electrode 110, a second sub-electrode 120, a third sub-electrode 130, and a fourth sub-electrode 140, respectively disposed to correspond to the first sub-pixel PX1, the second sub-pixel PX2, the third sub-pixel PX3, and the fourth sub-pixel PX4.

In particular, the first sub-electrode 110 is disposed to correspond to (or overlap) the first sub-pixel PX1 that emits red light, and the second sub-electrode 120 is disposed to correspond to (or overlap) the second sub-pixel PX2 that emits green light. The third sub-electrode 130 is disposed to correspond to (or overlap) the third sub-pixel PX3 that emits yellow light, and the fourth sub-electrode 140 is disposed to correspond to (or overlap) the fourth sub-pixel PX4 that emits blue light.

The first sub-electrode 110, the second sub-electrode 120, the third sub-electrode 130, and the fourth sub-electrode 140 forming the first electrode 100 are disposed to be spaced apart from each other. The first to fourth sub-electrodes 110, 120, 130, and 140 may be formed by coating a material that forms the first electrode 100 on the substrate S, and performing a photolithography process thereon.

The first electrode 100 may include a transparent conductive material, such as, indium tin oxide (ITO), indium zinc oxide (IZO), zinc oxide (ZnO), or indium oxide (In₂O₃) or a reflective metal, such as, lithium (Li), calcium (Ca), lithium fluoride/calcium (LiF/Ca), lithium fluoride/aluminum (LiF/Al), aluminum (Al), silver (Ag), magnesium (Mg), or gold (Au). For example, the first electrode 100 may be formed by sequentially disposing (or layering) ITO, Ag, and ITO. The first electrode 100 may be an anode of the organic light emitting diode (OLED).

A first organic emission layer 210 is disposed on the first electrode 100. The first organic emission layer 210 emitting blue light may be disposed on the first electrode 100 as a common layer. More specifically, the first organic emission layer 210 emitting blue light is integrally disposed on the first sub-electrode 110, the second sub-electrode 120, the third sub-electrode 130, and the fourth sub-electrode 140. More particularly, the first organic emission layer 210 disposed on the first sub-electrode 110, the second sub-electrode 120, the third sub-electrode 130, and the fourth sub-electrode 14 is disposed as a single layer, rather than being separated.

The first organic emission layer 210 may be formed by coating an organic material on the first electrode 100, which may not utilize a mask. In this case, the first organic emission layer 210 may be a first sub-emission layer including a host and a dopant. The first sub-emission layer may include a blue host and dopant with a constant ratio.

According to the present exemplary embodiment, a second organic emission layer 300 is disposed on the first organic emission layer 210. In this case, the second organic emission layer 300 is disposed to correspond to (or overlap) the first, second, and third sub-electrodes 110, 120, and 130, and may not be disposed on the fourth sub-electrode 140.

The second organic emission layer 300 is integrally formed with the first sub-electrode 110, the second sub-electrode 120, and the third sub-electrode 130. That is, the second organic emission layer 300 is disposed on the first to third sub-electrodes 110, 120, and 130, rather than being separated within one pixel. The second organic emission layer 300 may be formed by coating an organic material using a mask, which may be configured to not form a pattern on the fourth sub-electrode 140.

The second organic emission layer 300 includes a third sub-emission layer 310 and a fourth sub-emission layer 320. The third sub-emission layer 310 includes a yellow host and dopant with a constant ratio. The fourth sub-emission layer 320 includes a dopant and may not include a host. The fourth sub-emission layer 320 allows holes transmitted through a hole injection layer 410 and a hole transport layer 430 shown in FIG. 4, to be smoothly injected to the third sub-emission layer 310. According to an exemplary embodiment of the present invention, when the hole injection layer 410 and the hole transport layer 430 (see FIG. 4) are not included in a pixel, the fourth sub-emission layer 320 may be omitted.

When forming the second organic emission layer 300 including the third sub-emission layer 310 and the fourth sub-emission layer 320, a single mask may be utilized to respectively form the third sub-emission layer 310 and the fourth sub-emission layer 320. That is, two masks are used when forming the second organic emission layer 300. In this manner, the number of masks utilized to form the first and second organic emission layers 210 and 300 may be reduced, as compared to a conventional process, which may utilize three masks for forming red, green, and blue organic emission layers. Accordingly, according to the present exemplary embodiment, the manufacturing process time and associated costs of the OLED display may be reduced.

A second electrode 400, which may be a common electrode, is disposed on the second organic emission layer 300. The second electrode 400 is disposed on the first sub-pixel PX1, the second sub-pixel PX2, the third sub-pixel PX3, and the fourth sub-pixel PX4 in common. More specifically, the second electrode 400 is integrally formed to correspond (or overlap) to the first sub-electrode 110, the second sub-electrode 120, the third sub-electrode 130, and the fourth sub-electrode 140. That is, the second electrode 400 disposed to correspond to each of the first sub-pixel PX1, the second sub-pixel PX2, the third sub-pixel PX3, and the fourth sub-pixel PX4 is formed as a common layer, rather than being separated.

The second electrode 400 may include a transparent conductive material or a transflective conductive material, such as, indium tin oxide (ITO), indium zinc oxide (IZO), zinc oxide (ZnO), or indium oxide (In₂O₃). The second electrode 400 may be a cathode of the organic light emitting diode OLED. As described, the first electrode 100, the first organic emission layer 210, the second organic emission layer 300, and the second electrode 400 may form the organic light emitting diode OLED.

According to the present exemplary embodiment, the color filter layer 600 is disposed on the second electrode 400. The color filter layer 600 may include sub-color filters, each having a different color. The color filter layer 600 may include a first sub-color filter 610 of red, a second sub-color filter 620 of green, a third sub-color filter 630 of yellow, and a fourth sub-color filter 640 of blue.

The first sub-color filter 610, the second sub-color filter 620, the third sub-color filter 630, and the fourth sub-color filter 640 are respectively disposed to correspond to (or overlap) the first sub-pixel PX1, the second sub-pixel PX2, the third sub-pixel PX3, and the fourth sub-pixel PX4. That is, the first sub-color filter 610 is disposed to correspond to the first sub-pixel PX1 that is configured to emit red light, and the second sub-color filter 620 is disposed to correspond to the second sub-pixel PX2 that is configured to emit green light. The third sub-color filter 630 is disposed to correspond to the third sub-pixel PX3 that is configured to emit yellow light, and the fourth sub-color filter 640 is disposed to correspond to the fourth sub-pixel PX4 that is configured to emit blue light.

The first sub-color filter 610, the second sub-color filter 620, the third sub-color filter 630, and the fourth sub-color filter 640 are disposed to be spaced apart from each other. The first sub-color filter 610, the second sub-color filter 620, the third sub-color filter 630, and the fourth sub-color filter 640 are respectively disposed in paths of light, which is emitted from the first organic emission layer 210 and the second organic emission layer 300 disposed in the first sub-pixel PX1, the second sub-pixel PX2, the third sub-pixel PX3, and the fourth sub-pixel PX4, respectively.

In the present exemplary embodiment, the first organic emission layer 210 and the second organic emission layer 300 simultaneously emit light in the first, second, and third sub-pixels PX1, PX2, and PX3, such that white light is emitted from the organic emission layer. In this case, white light passes through the first sub-color filter 610 of red and displays red in the first sub-pixel PX1, and white light passes through the second sub-color filter 620 of green and displays green in the second sub-pixel PX2. In the third sub-pixel PX3, white light passes through the third sub-color filter 630 of yellow and displays yellow. In the fourth sub-pixel PX4, however, only the first organic emission layer 210 emitting blue light is disposed therein. Accordingly, blue light passes through the fourth sub-color filter 640 of blue, and thus blue light is displayed in the fourth sub-pixel PX4.

According to the present exemplary embodiment, the first sub-pixel PX1, the second sub-pixel PX2, and the third sub-pixel PX3 may respectively realize red, green, and yellow light using white light. Conventionally, red and green light are respectively emitted from the corresponding organic emission layers disposed in red and green sub-pixels.

According to the present exemplary embodiment, white light generated by a combination of blue light of the first organic emission layer 210 and yellow light of the second organic emission layer 300 passes through the first sub-color filter 610, the second sub-color filter 620, and the third sub-color filter 630, such that red, green, and yellow light may be displayed. In this manner, in the first to third sub-pixels PX1, PX2, and PX3, only white light is utilized to emit red, green, and yellow. As such, a display device according to the present exemplary embodiment may be driven with lower current, compared to a conventional structure emitting red light and green light individually. That is, power consumption of the display device may be reduced.

Hereinafter, a structure of the a first organic emission layer that emits blue light will be described in detail with reference to FIGS. 1 to 3. According to an exemplary embodiment of the present invention, degradation of the life-cycle of the organic emission layer may be prevented by increasing the area of the first organic emission layer.

Referring to FIG. 1 and FIG. 3, according to the present exemplary embodiment, the area of the fourth blue sub-pixel PX4 is formed to be greater than the area of each of the first to third sub-pixels PX1, PX2, and PX3. As used herein, the area of each of the first to fourth sub-pixels PX1, PX2, PX3, and PX4 denotes an exposure area of each of the first to fourth sub-electrodes 110, 120, 130, and 140.

As the area of each of the first to fourth sub-electrodes 110, 120, 130, and 140 is increased, the area of an organic emission layer disposed on the first to fourth sub-electrodes 110, 120, 130, and 140 may be increased. The area of each of the first to third sub-pixels PX1, PX2, and PX3 may be substantially equal to each other. For example, the area of the first to third sub-pixels PX1, PX2, and PX3 may be respectively defined by the product of a length of A1, A2, and A3 in the X direction and a length B1, B2, and B3 in the Y direction crossing crosses the X direction. In this case, the X directional lengths A1, A2, and A3 of the first to third sub-pixels PX1, PX2, and PX3 are substantially equal to each other, and the Y directional lengths are substantially equal to each other.

According to an exemplary embodiment of the present invention, at least two of the first to third sub-pixels PX1, PX2, and PX3 may be formed to have different areas from each other, as long as the area of each of the first to third sub-pixels PX1, PX2, and PX3 is formed to be smaller than the area of the fourth sub-pixel PX4. For example, the X-directional length A1, A2, and A3 of the first to third sub-pixels PX1, PX2, and PX3 may be substantially equal to one another, and the Y-directional length B1, B2, and B3 thereof may be different from each other. Referring back to FIG. 3, an encapsulation layer 700 may be disposed on the color filter layer 600. The encapsulation layer 700 may protect the organic emission layer and a driving circuit (not shown) from an external environment by sealing the organic emission layer and the driving circuit (not shown).

The encapsulation layer 700 according to the present exemplary embodiment may be an encapsulation member that uses a sealant for sealing. The sealant used as the encapsulation member may include various materials, such as, glass, quartz, ceramic, plastic, metal, and the like. A thin-film encapsulation layer may be alternatively formed by depositing an inorganic layer and an organic layer on the second electrode 400, without using the sealant. The thin film encapsulation layer includes encapsulation organic layers and encapsulation inorganic layers, each being alternately layered. For example, each of two encapsulation organic layers and each of two encapsulation inorganic layers may be alternately layered to form the encapsulation layer 700.

Referring to FIG. 4, according to an exemplary embodiment of the present invention, a hole injection layer 410, a hole transport layer 430, and an electrode transport layer 440 may be disposed between the first electrode 100 and the second electrode 400. A second sub-emission layer 220 is disposed below a first sub-emission layer 210. The second sub-emission layer 220 includes a dopant and may not include a host. The second sub-emission layer 220 allows smooth injection of a hole transmitted through hole auxiliary layers 410 and 430 to the first sub-emission layer 210.

The hole injection layer 410 is integrally formed on the first electrode 100. That is, the hole injection layer 410 is integrally formed on the first sub-electrode 110, the second sub-electrode 120, the third sub-electrode 130, and the fourth sub-electrode 140. The hole injection layer 410 may assist with smooth injection of the holes injected from the first electrode 100, which is a positive electrode, into first and second organic emission layers.

The hole transport layer 430 may be disposed between the hole injection layer 410 and the second sub-emission layer 220. The hole transport layer 430 may be integrally formed on the hole injection layer 410. The hole transport layer 430 may help with easily transporting the holes injected to the organic emission layer from the first electrode 100 through the hole injection layer 410.

The electron transport layer 440 is disposed between the second organic emission layer 300 and the second electrode 400. The electron transport layer 440 may be integrally formed corresponding to the first to fourth sub-pixels PX1, PX2, PX3, and PX4. The electron transport layer 440 may help the electrons injected from the second electrode 400, which are negative electrodes, to be smoothly injected into the organic emission layer.

In an OLED display according to exemplary embodiments of the present invention, the first sub-pixel PX1, the second sub-pixel PX2, and the third sub-pixel PX3 may respectively realize red, green, and yellow color, by passing white light combined from blue light emitted from the first organic emission layers 200, 210, and 220 and yellow light emitted from the second organic emission layers 300, 310, and 320, through the respective color filter layers 600.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. An organic light emitting diode (OLED) display, comprising:
a substrate;
a first electrode disposed on the substrate, the first electrode comprising:
a first sub-electrode, a second sub-electrode, a third sub-electrode, and a fourth sub-electrode spaced apart from each other;
first organic emission layers disposed on the first sub-electrode, the second sub-electrode, the third sub-electrode, and the fourth sub-electrode;
second organic emission layers disposed on the first organic emission layers, the second organic emission layers overlapping the first, second, and third sub-electrodes;
a second electrode disposed on the second organic emission layers, the second electrode overlapping the first, second, third, and fourth sub-electrodes; and
a color filter layer disposed on the second electrode, the color filter layer comprising sub-color filters.

2. The OLED display of claim 1, wherein the color filter layer comprises a first sub-color filter, a second sub-color filter, a third sub-color filter, and a fourth sub-color filter respectively overlapping the first sub-electrode, the second sub-electrode, the third sub-electrode, and the fourth sub-electrode.

3. The OLED display of claim 2, wherein the first sub-color filter is a red color filter, the second sub-color filter is a green color filter, the third sub-color filter is a yellow color filter, and the fourth sub-color filter is a blue color filter.

4. The OLED display of claim 1, wherein:
the first organic emission layers comprise a first sub-emission layer disposed on the first electrode; and
the first sub-emission layer comprises a host and a dopant.

5. The OLED display of claim 4, wherein the first sub-emission layer is integrally formed.

6. The OLED display of claim 4, wherein:
the first organic emission layers further comprise a second sub-emission layer disposed between the first electrode and the first sub-emission layer; and
the second sub-emission layer comprises a dopant.

7. The OLED display of claim 6, wherein the second sub-emission layer is integrally formed.

8. The OLED display of claim 1, wherein the first organic emission layers comprise a blue emission layer.

9. The OLED display of claim 1, wherein:
the second organic emission layers comprise a third sub-emission layer disposed on the first organic emission layers; and
the third sub-emission layer comprises a host and a dopant.

10. The OLED display of claim 9, wherein the third sub-emission layer is integrally formed.

11. The OLED display of claim 9, wherein:
the second organic emission layers further comprise a fourth sub-emission layer disposed between the first organic emission layers and the third sub-emission layer; and
the fourth sub-emission layer comprises a dopant.

12. The OLED display of claim 11, wherein the fourth sub-emission layer is integrally formed.

13. The OLED display of claim 1, wherein the second organic emission layers are a yellow emission layer.

14. The OLED display of claim 1, wherein the second electrode is integrally formed.

15. The OLED display of claim 1, further comprising an encapsulation layer disposed on the color filter layer.

16. The OLED display of claim 1, further comprising:
a hole injection layer disposed between the first electrode and the first organic emission layers;
a hole transport layer disposed between the hole injection layer and the first organic emission layers; and
an electron transport layer disposed between the second organic emission layers and the second electrode.

17. The OLED display of claim 1, further comprising a pixel, the pixel comprising a first sub-pixel, a second sub-pixel, a third sub-pixel, and a fourth sub-pixel,
wherein:
the first, second, third, and fourth sub-pixels respectively comprise the first, second, third, and fourth sub-electrodes; and
an area of the each of the first, second, and third sub-pixel is less than an area of the fourth sub-pixel.

18. The OLED display of claim 1, wherein the second electrode is a transparent electrode.

19. A method of forming an organic light emitting diode (OLED) display, the method comprising:
forming a first electrode on a substrate, the substrate comprising:
a first area comprising a first sub-electrode, a second sub-electrode, a third sub-electrode of the first electrode; and
a second area comprising a fourth sub-electrode of the first electrode;
forming a first organic emission layer in the first and second areas;
forming a second organic emission layer in the first area;
forming a second electrode in the first and second areas; and
forming a color filter layer on the second electrode;
wherein the first and second organic emission layers are respectively configured to emit blue and yellow light.

20. The method of claim 19, wherein the first organic emission layer is disposed over an entire surface of the first electrode without using a mask.
